(19) United States
(12) Patent Application Publication
(10) Pub. No.: US 2012/0298201 A1
(43) Pub. Date: Nov. 29, 2012

(54) SOLAR PANEL RACKING SYSTEM

(76) Inventor: Erich Kai Stephan, Huntington Beach, CA (US)

(21) Appl. No.: 13/300,275

(22) Filed: Nov. 18, 2011

(51) Int. Cl. H01L 31/045

(52) U.S. Cl. 136/259

(57) ABSTRACT

Photovoltaic modules that are collapsible and angularly adjustable are made by mounting a photovoltaic panel in a frame, with a leg joined to the frame, the leg being manually adjustable to various angles, tilting the frame at various angles relative to the horizontal by simply lifting the frame. Certain embodiments also include interlocking features that join adjacent frames to form a rectangular array of modules.

### BACKGROUND OF THE INVENTION

1. Field of the Invention

This invention resides in the field of mounting structures for photovoltaic panels.

2. Description of the Prior Art

The cost of photovoltaic panels is volatile because of such factors as government subsidies, foreign competition, changes in the costs of materials, and advances in the technology of photovoltaics including the introduction of new materials and the replacement of costly materials with those that are cheaper or more readily available. These factors have affected the cost of manufacture, purchase, and installation of the panels, but they have also prompted the use of innovative marketing strategies, such as the leasing of photovoltaic modules rather than purchase and the limiting of customer charges to a periodic use fee without charging the customer for installation. One result of these innovations and variations is that the cost contributions other than those of the panels themselves have become increasingly prominent factors in the financial structures of photovoltaics providers. Non-panel-related cost contributions can include, for example, the costs of storage, transport, and labor, including the ease and rapidity of deployment of the panels and their removal when necessary for termination of use, reconstruction of the deployment site, or replacement of the panels.

### SUMMARY, OBJECTS AND ADVANTAGES

Photovoltaic modules are described herein that are collapsible and angularly adjustable by hand, with particular embodiments including features that permit stacking or nesting of the modules for ease of storage and transport, and rapid placement, alignment, and adjustment for quick deployment, including the stable joining of multiple such modules in an array that makes maximal use of any given exposure area. These features can be achieved in a lightweight structure that does not require roof penetration. The structure includes a frame with the photovoltaic panel mounted inside the frame, and a leg joined to the frame at various angles relative to the frame, such that one of the two end edges of the frame can be placed at different heights relative to the opposing end edge of the frame, thereby holding the frame and the photovoltaic panel at any of different angles relative to the horizontal when the module is placed on a horizontal surface, one of the angles being zero relative to the horizontal or to the surface on which the module is placed, i.e., placing the panel being parallel to the surface. In certain embodiments, the joinder of the leg to the frame can be adjusted to achieve two or more angles above the horizontal (or surface), thereby offering a choice of tilt angles for the photovoltaic panel and a rapid switching among the various angles. The module can thus be placed on any horizontal surface, with or without securement to the surface or to the substructure supporting the surface, and yet the entire module, including all features that control the angle of the photovoltaic panel, are integrated into the module with minimal or no need for on-site assembly of additional parts.

The zero-angle option places the module in a flat, or generally flat, configuration, i.e., collapsing the module and allowing two or more modules to be stacked without dismantling the photovoltaic panel from the frame or the supporting leg. The resulting stack consumes a minimum of spatial volume, allowing for high-volume shipping with restricted cargo space and a high storage capacity in restricted bin or warehouse space. In certain embodiments of the invention, the module further includes an interlocking feature that allows for the stable joining of multiple modules as mentioned above. This feature includes extensions of the frame, either laterally or longitudinally, with joining features on the extensions so that extensions on one module can be joined to extensions on an adjacent module. In some cases, each extension on one module can be joined to extensions on two adjacent modules positioned along adjacent edges of the rectangular frame of the first module, i.e., one neighboring module adjacent to an end edge of a central module and another neighboring module adjacent to a side edge of the central module, both joined to the central module through the same extension. This allows multiple modules to be formed into a rectangular array with all modules connected. Still further features and embodiments of the invention will be apparent from the description that follows.

### BRIEF DESCRIPTION OF THE DRAWINGS

FIG. 1A is a side view of a photovoltaic module representing one example of the present invention.

FIG. 1B is a side view of the module of FIG. 1A in a collapsed configuration.

FIG. 1C is a top view of the module of FIG. 1A.

FIG. 2 is a side view of a photovoltaic module representing a second example of the present invention.

FIG. 3 is a side view of a stack of collapsed photovoltaic modules of the construction of FIGS. 1A, 1B, and 1C.

FIG. 4A is vertical cross section of a photovoltaic module representing a second example of the present invention.

FIG. 4B is a vertical cross section of the module of FIG. 4A with the frame at a lower angle than that of FIG. 4A.

FIG. 4C is a top view of the module of FIGS. 4A and 4B.

FIG. 5 is a vertical cross section of a photovoltaic module representing a third example of the present invention.

FIG. 6 is a vertical cross section of a photovoltaic module representing a fourth example of the present invention.

FIG. 7A is a vertical cross section of a photovoltaic module representing a fourth example of the present invention.

FIG. 7B is a vertical cross section of the photovoltaic module of FIG. 7A with the photovoltaic panel at a lower angle than that of FIG. 7A.

FIG. 7C is a vertical cross section of the photovoltaic module of FIGS. 7A and 7B in a collapsed configuration.

FIG. 8 is a side view of a stack of collapsed photovoltaic modules of the design shown in FIGS. 7A, 7B, and 7C.

FIG. 9A is a vertical cross section of a photovoltaic module representing a fifth example of the present invention.

FIG. 9B is a vertical cross section of the photovoltaic module of FIG. 9A with the photovoltaic panel at a lower angle than that of FIG. 9A.

FIG. 10A is a vertical cross section of a photovoltaic module representing a sixth example of the present invention.

FIG. 10B is a vertical cross section of the photovoltaic module of FIG. 10A with the photovoltaic panel at a lower angle than that of FIG. 10A.

FIG. 11 is a top view of an array of photoelectric modules of FIGS. 4A, 4B, 4C, 5, 6, 7A, and 7B.

### DETAILED DESCRIPTION OF SELECTED EMBODIMENTS

While novel concepts of the invention herein are susceptible to numerous embodiments and implementations, they will be best understood by a detailed examination of certain specific embodiments. Such embodiments are depicted in the Figures and described below.

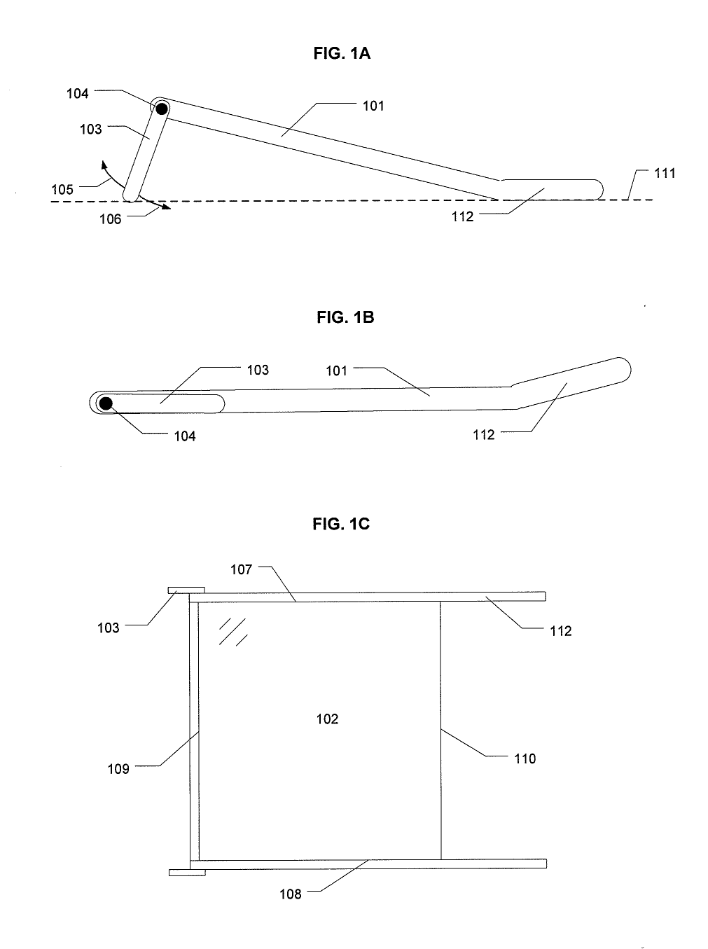

FIGS. 1A, 1B, and 1C are three views of a module that includes a frame 101 in which the flat, rectangular photovoltaic panel 102 (FIG. 1C) is mounted. The module also includes an articulating leg 103 that is pivotally attached to the frame at a pivot joint 104 along the directions of the arrows 105, 106 (FIG. 1A), or at least in the direction of one arrow 106. The photovoltaic panel 102 is rectangular and has a pair of lateral edges 107, 108 and a pair of end edges 109, 110, and the pivot joint 104 allows the leg 103 to rotate about an axis parallel to the end edges 109, 110. FIGS. 1A and 1B depict the leg 103 in two positions, the first position placing one end edge 109 of the panel at a greater height relative to the horizontal 111 than the other end edge 110, and the second position placing the two end edges at the same height and thereby collapsing the entire module to a flat configuration. A portion 112 of the frame 101 is angled such that this portion will be horizontal when the articulating leg 103 is angled and the left end edge 109 is raised to the position shown in FIG. 1A. This angled portion 112 of the frame is one of various optional features that can add to the stability of the module on the horizontal surface represented by dashed line 111.

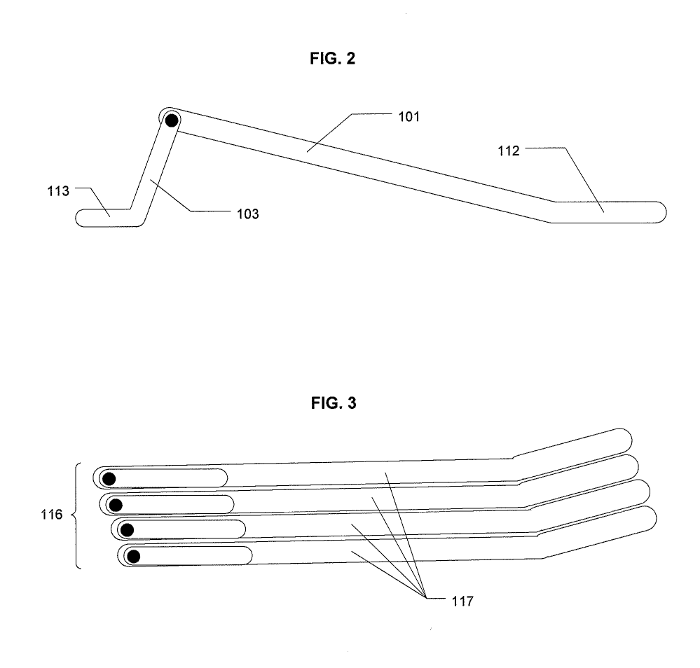

Another optional feature is an angled portion 113 of the articulating leg 103 as shown in the variation depicted in FIG. 2. This angled portion 113 serves the same purpose as the angled portion 112 of the frame.

FIG. 3 depicts a stack 116 of individual modules 117 of the construction shown in FIGS. 1A, 1B, and 1C, demonstrating how space can be saved by the module construction. Each of the modules 117 is in the collapsed or flattened position, thereby minimizing the height of the stack. Although not shown in this view, the modules can be in nested form in the stack when portions of each module are more widely spaced than other portions. The articulating leg 103, for example, can reside on the outer surfaces of the frame 101, and when the articulating leg has an angled portion 113 as shown in FIG. 2, the angled portion will extend above the frame when the module is collapsed. Any module lying on top of an underlying module will then reside within the space between the two upwardly protruding angled portions 113, thereby forming a nested stack. A similar effect is achieved with other upwardly protruding portions.

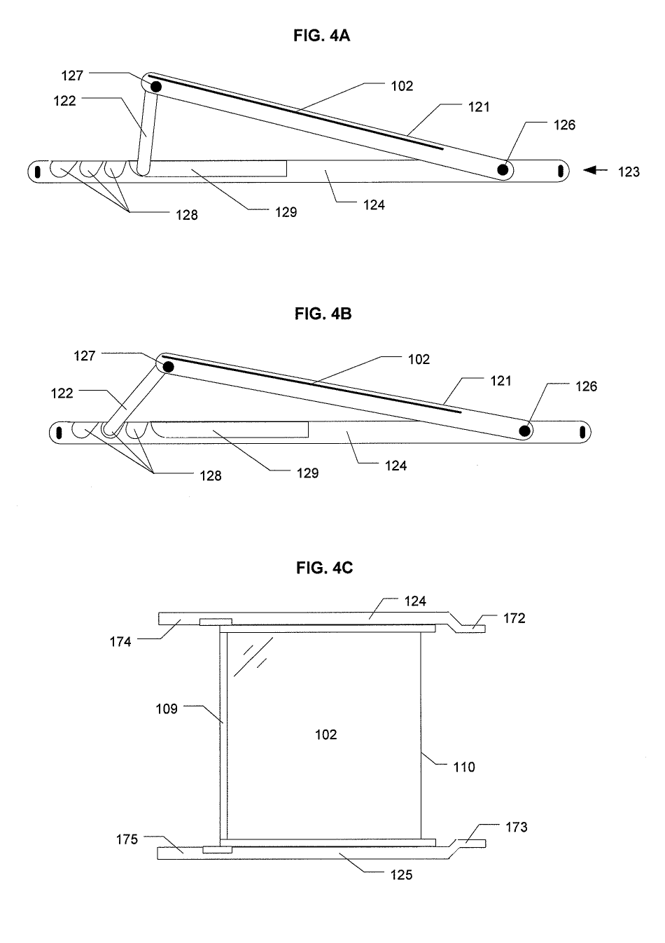

FIGS. 4A, 4B, and 4C depict an alternative embodiment of a module within the scope of the invention, in an internal view of one side of the module, i.e., a cross section taken along a central plane bisecting the module along its length. The frame 121 and articulating leg 122 in this module are supplemented by a base 123 which includes a pair of horizontal rails, one of which 124 is visible in FIGS. 4A and 4B, and both of which 124, 125 are visible in FIG. 4C. In this embodiment, the rails of the frame 121 are pivotally affixed to one end to the base 123 at pivot joints, only one of which 126 is visible in FIGS. 4A and 4B, the pivot joints being at the end of the frame opposite the end where the articulating leg 122 is attached through its own pivot joint 127. The base rails 124, 125 each contain a series of notches or indentations 128 and an elongated indentation 129, all to receive the lower end of the articulating leg 122. The different notches 128 are placed at a succession of positions along the length of the base rail, thereby setting different angles and hence different heights for the articulating leg 122, while the elongated indentation 129 allows the articulating leg 122 to fold completely and lower the frame fully down to a position alongside and parallel with the base 123, thereby placing the module in a fully collapsed condition.

FIG. 5 depicts a second alternative. This alternative includes a frame 131, articulating leg 132, and base 133 as in the embodiment of FIGS. 4A, 4B, and 4C. In the embodiment of FIG. 5, however, the notches 134 are in the frame 131 rather than the base 133, and both the lower end 136 of the frame and the lower end 137 of the leg are mounted to the base and limited to pivoting movement while the upper end 138 of the leg is free. An elongated indentation 135 is included in the base 133 to allow the leg to fold into the elongated indentation for collapsing the frame into the base. Different angles of the frame 131 relative to the horizontal base, one shown in solid lines and the other in dashed lines, are achieved by placing the upper end 138 of the leg in different notches or indentations 134, while full lowering of the frame can be achieved by either placing the upper end 138 of the leg in the elongated indentation 135. The notches 134 in this embodiment are on the outside of the frame 131 (and therefore shown in dashed lines) and the frame 131 when collapsed fits inside the base 133.

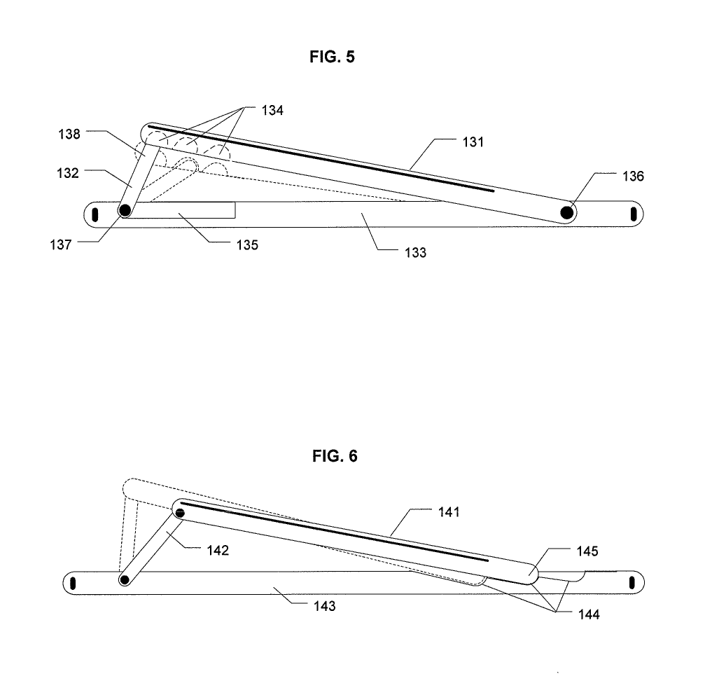

A third alternative is shown in FIG. 6. Here again, the module includes a frame 141, an articulating leg 142, and a base 143 as in the embodiment of FIGS. 4A, 4B, and 4C. The notches 144 are in the base 143, but in positions where they engage the lower end 145 of the frame rather than the articulating leg 142. Different angles of the frame 141 relative to the horizontal base 143, again shown in solid and dashed lines, are achieved by placing the lower end 145 of the frame in different notches 144, while full lowering of the frame can be achieved by removing the lower end of the frame from the notches entirely.

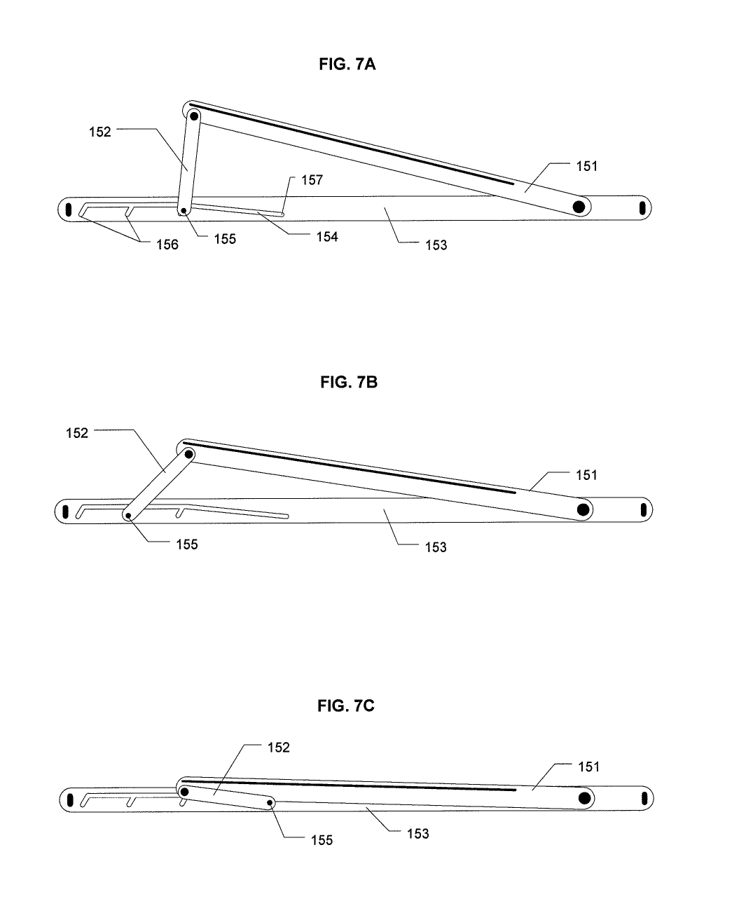

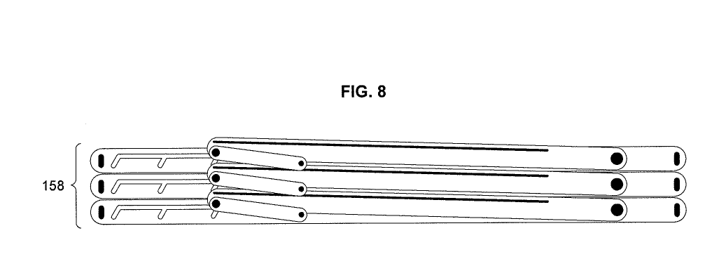

A fourth alternative is shown in FIGS. 7A, 7B, and 7C, which show a module with the frame at three different angles, respectively, the third (FIG. 7C) being horizontal or nearly horizontal. The frame 151, articulating leg 152, and base 153 are analogous to those of FIGS. 4A, 4B, and 4C, but the notches and elongated indentation are replaced with an elongated slot 154 through which a pin 155 at the lower end of the articulating leg passes. The two extremities of the slot 154 allow the leg 152 to be stabilized in either of two positions, respectively. A series of internal indentations 156 within the slot 154 and between the two extremities of the slot allow the pin to enter these indentations and thereby establish intermediate non-sliding positions for the lower end of the articulating leg. These indentations offer a choice between different raised angles of the frame (FIGS. 7A and 7B), while sliding the pin 155 to the extreme inner end 157 of the slot places the frame at an approximately zero angle or flattened position (FIG. 7C). Multiple modules 158 stack easily, as shown in FIG. 8.

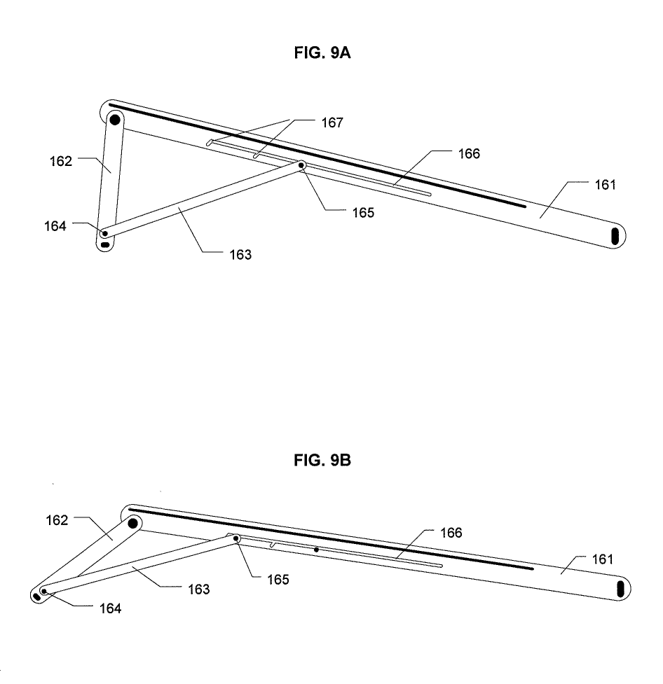

A fifth alternative is shown in FIGS. 9A and 9B. The module in these figures has a frame 161 and an articulated leg 162 but no base. A connecting bar 163 joins the lower end of the articulating leg 162 to the frame 161. The joint 164 between the connecting bar 163 and the articulating leg 162 is a pivot joint, and the connection between the connecting bar 163 and the frame 161 is a pin 165 on the connecting bar 163 that travels within a guide slot 166 on the frame similar to the guide slot 154 in the embodiment of FIGS. 7A, 7B, and 7C. Internal indentations 167 in the guide slot 166 serve the same function as the indentations 156 in the guide slot of FIGS. 7A, 7B, and 7C.

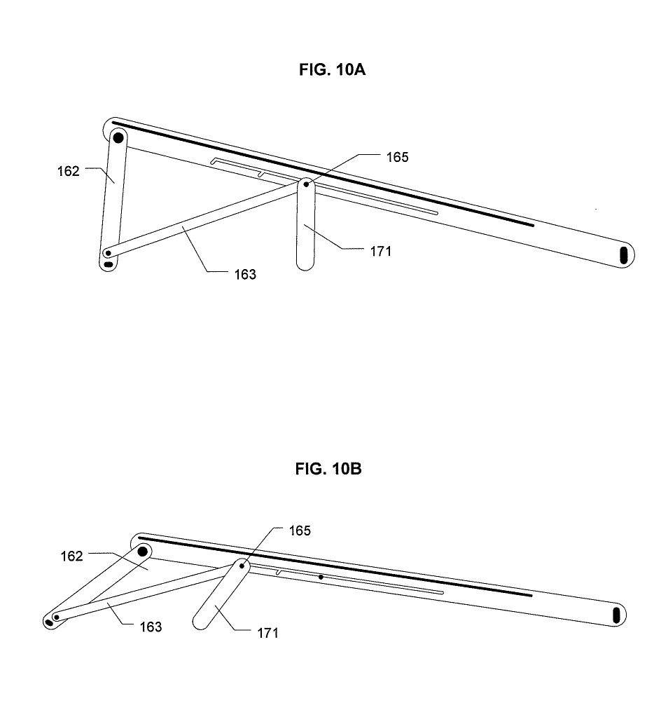

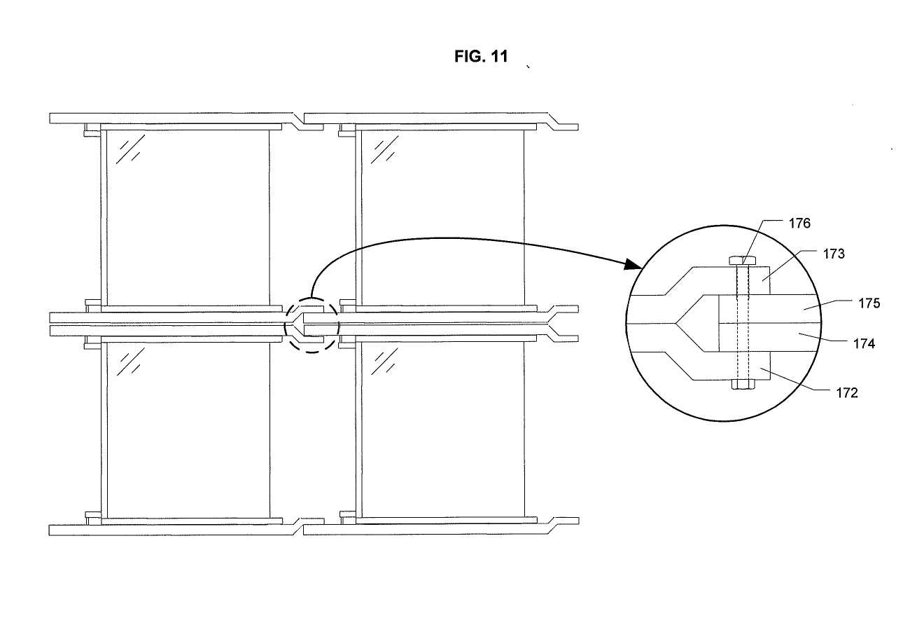

A sixth alternative is shown in FIGS. 10A and 10B. This module is identical to the module of FIGS. 9A and 9B except for the addition of a supplementary articulated leg 171 joined to the upper end of the connecting bar 163 by a pivot joint at the same location as the pin 165. The supplementary leg 171 provides further stability to the module when resting on a flat surface.

An example of a connecting structure by which adjacent modules can be joined to each other is seen in part in FIG. 4C, where the two base rails 124, 125 extend beyond the end edges 109, 110 of the photovoltaic panel and the extended lengths at one end are turned inward to form short parallel tabs 172, 173. These tabs are closer together than the extensions 174, 175 at the opposite ends of the base rails. The tabs 172, 173 of one module can thus fit within the extensions 174, 175. The cross section views of FIGS. 4A and 4B show that the extended lengths at both ends contain apertures in both the tabs 172, 173 and the wider extensions 174, 175. When the apertures are aligned, fasteners of any conventional construction can be passed through the apertures to secure the tabs to the wider extensions. Cotter pins are examples of such fasteners, although bolts of any description can also be used. FIG. 11 depicts the use of these tabs 172, 173 and wider extensions 174, 175 to join four modules together in a rectangular array, with a suitably long fastener 176 to pass through four aligned apertures. In an alternative arrangement, the extensions and tabs can extend laterally rather than longitudinally as shown, to analogous effect.

When two components of a modules are described herein as being “pivotally affixed” to each other, this means that the two components are joined together in manner that does not permit them to be disengaged from each other by hand (i.e., without the use of additional tools), and that they can be moved relative to each other in a rotational degree of freedom only and within a single plane.

In all embodiments of this invention, the frame in which the photovoltaic panel is mounted can be a frame that either contacts all four edges of the panel and thereby fully surrounds the panel, or contacts less than all four edges. An example of a frame that contacts less than all four edges is one that contacts only the two longitudinal edges and one end edge, leaving the remaining end edge exposed, as shown in FIG. 1C. In all cases, however, the frame is integral with the articulating leg, either directly or through the connecting bar, and thereby with any other structurally supporting parts of the module. In this respect, modules in accordance with this invention can offer an advantage over those of the prior art where the photovoltaic panel is enclosed in an aluminum frame which is then secured to an aluminum or steel substructure with such fasteners as bolts or clips. By contrast, modules with integrated frames in accordance with this invention can eliminate both the separate frame and the need for bolts or clips as additional components to be used for assembly. In addition to user convenience and speed in deployment, benefits from eliminating the separate frame include a reduction in the weight of the overall system and avoidance of the need to electrically connect all frames in a multi-module array to a common electrical ground.

Further components of a photovoltaic system, although not shown in the drawings, can be incorporated into or connected to the module. For example, an inverter of any conventional design for converting the DC electrical current generated by the photovoltaic panel to an AC current can be attached to the back of each photovoltaic panel, or to the frame, or included as a separate component joined to multiple modules in the array through conventional electrical connections. Alternatively or in addition, a wire management system such as gutters or small clips can be included to organize the wires from each panel and allow for easy access and connections. Another example is the inclusion of a ballast between the extended portions of the base rails to add to the structure rigidity of the module. A still further example is the inclusion of a wind deflector between the articulating legs on the two sides of the frame. Other examples will be readily apparent to those of skill in the structure and mounting of solar panels.

Individual modules and multi-module arrays as described above can be deployed on any horizontal or substantially horizontal surface that is exposed to the sun. Examples of such surfaces are open fields, paved areas, and roofs of structures such as residential and commercial buildings, storage sheds, warehouses, parking structures, and carports. Further examples will be readily apparent to those of skill in the solar energy industry.

In the claims appended hereto, the term “a” or “an” is intended to mean “one or more.” The term “comprise” and variations thereof such as “comprises” and “comprising,” when preceding the recitation of a step or an element, are intended to mean that the addition of further steps or elements is optional and not excluded. All patents, patent applications, and other published reference materials cited in this specification are hereby incorporated herein by reference in their entirety. Any discrepancy between any reference material cited herein or any prior art in general and an explicit teaching of this specification is intended to be resolved in favor of the teaching in this specification. This includes any discrepancy between an art-understood definition of a word or phrase and a definition explicitly provided in this specification of the same word or phrase.

What is claimed is:

1. A collapsible and angularly adjustable photovoltaic module comprising:
a photovoltaic panel comprising first and second end edges and retained in a frame, and
a leg engaging said frame to stably support said frame with said first end edge of said photovoltaic panel at any of a plurality of heights relative to said second end edge, thereby placing said photovoltaic panel at any of a plurality of angles relative to the horizontal when said frame lies on a horizontal surface, said leg being manually adjustable between said heights and said plurality of angles including a zero angle relative to the horizontal.

2. The photovoltaic module of claim 1 wherein said leg is pivotally affixed to said frame for rotation relative to said frame about an axis parallel to said first end edge.

3. The photovoltaic module of claim 2 further comprising a base to which said second end edge of said frame is pivotally affixed, and wherein said leg has first and second leg ends, said first leg end being pivotally affixed to said frame, and said base has at least one indentation to receive said second leg end and thereby stabilize said frame at an angle other than horizontal.

4. The photovoltaic module of claim 3 wherein said base has a plurality of indentations to receive said second leg end and thereby stabilize said frame at any of a plurality of angles other than the horizontal.

5. The photovoltaic module of claim 2 wherein said leg has first and second leg ends, said photovoltaic module further comprising a base to which said frame and said second leg end are pivotally affixed, and said frame has at least one indentation to receive said first leg end and thereby stabilize said leg at an angle other than the horizontal.

6. The photovoltaic module of claim 5 wherein said frame has a plurality of indentations to receive said first leg end and thereby stabilize said leg at any of a plurality of angles other than the horizontal.

7. The photovoltaic module of claim 2 further comprising a base to which said frame is pivotally affixed, and wherein said leg has first and second leg ends, said first leg end being pivotally affixed to said frame, and said base has a guide slot engaging said second leg end and thereby stabilizing said leg at either of first and second extremities of said guide slot.

8. The photovoltaic module of claim 8 further comprising a pin extending from said second leg end and a plurality of indentations in said guide slot to receive said pin, thereby allowing said leg to support said frame at a plurality of angles.

9. The photovoltaic module of claim 2 wherein said leg has first and second leg ends, said photovoltaic module further comprising a connecting bar pivotally affixed to said second leg end, said frame having a guide slot engaging said connecting bar and thereby stabilizing said connecting bar at either of first and second extremities of said guide slot.

10. The photovoltaic module of claim 10 further comprising a pin extending from said connecting bar and a plurality of indentations in said guide slot to receive said pin, thereby allowing said leg to support said frame at a plurality of angles.

11. The photovoltaic module of claim 1 wherein said frame has extensions extending beyond, and perpendicular to, opposing edges of said photovoltaic panel, said photovoltaic module further comprising means for joining said extensions of a first such photovoltaic module to said longitudinal extensions of a second such photovoltaic module.

12. The photovoltaic module of claim 7 wherein said extensions consist of a first pair at said first end of said frame and a second pair at said second end of said frame, said first pair being closer together than said second pair such that said first pair fits inside said second pair, said means for joining comprising apertures in either first pair, said second pair, or both said first and second pairs, and fasteners to engage said apertures.

13. The photovoltaic module of claim 3 wherein said base comprises first and second parallel base rails, and said frame further comprises first and second longitudinal edges, said first and second longitudinal edges of said frame being closer together than said first and second base rails, thereby allowing said frame to reside between said base rails when said frame is collapsed to a zero angle relative to the horizontal.

14. The photovoltaic module of claim 5 wherein said base comprises first and second parallel base rails, and said frame further comprises first and second longitudinal edges, said first and second longitudinal edges of said frame being closer together than said first and second base rails, thereby allowing said frame to reside between said base rails when said frame is collapsed to a zero angle relative to the horizontal.

15. The photovoltaic module of claim 7 wherein said base comprises first and second parallel base rails, and said frame further comprises first and second longitudinal edges, said first and second longitudinal edges of said frame being closer together than said first and second base rails, thereby allowing said frame to reside between said base rails when said frame is collapsed to a zero angle relative to the horizontal.

16. The photovoltaic module of claim 9 wherein said base comprises first and second parallel base rails, and said frame further comprises first and second longitudinal edges, said first and second longitudinal edges of said frame being closer together than said first and second base rails, thereby allowing said frame to reside between said base rails when said frame is collapsed to a zero angle relative to the horizontal.
